(19) United States
(12) Patent Application Publication
(10) Pub. No.: US 2012/0105046 A1
(43) Pub. Date: May 3, 2012

(54) CURRENT MIRROR USING AMBIPOLAR DEVICES

(75) Inventors: Andrew Marshall, Dallas, TX (US); Ashesh Parikh, Frisco, TX (US)

(73) Assignee: Texas Instruments Incorporated, Dallas, TX (US)

(21) Appl. No.: 12/914,661

(22) Filed: Oct. 28, 2010

(51) Int. Cl. G05F 3/16

(52) U.S. Cl. 323/315; 977/938

(57) ABSTRACT

Current mirrors have been used in analog electronics with both CMOS and bipolar transistors for many years. Conventional current minor designs, though, may not be suitable for emerging technology transistors, such as graphene transistors, carbon nanotube (CNT) transistors, or other ambipolar transistors. Here, a current minor has been provided that uses ambipolar transistors, which accounts for the more unusual I-V (drain current to gate-source voltage) characteristics of ambipolar transistors.

### TECHNICAL FIELD

The invention relates generally to current minors and, more particularly, to current minors that employ ambipolar devices.

### BACKGROUND

Turning to FIG. 1, a conventional current mirror 100 can be seen. This current minor 100 is generally comprised of NMOS transistors Q1 and Q2. Because transistors Q1 and Q2 are generally matched, having approximately the same size or aspect ratio (ratio of channel width to channel length), the reference current IREF (which is applied to the diode-connected transistor Q1) can be mirrored by driven transistor Q2 (generating a mirrored current IMIRROR). A reason for this behavior can be attributed to the behavior of the transistors Q1 and Q2, namely the I-V characteristics or I-V curves of NMOS transistors. As shown in FIG. 2, the drain current ID remains relatively constant at large drain-source voltages VGS and increases (almost linearly) at low drain-source voltages VGS. The mirrored current IMIRROR or output current versus output voltage VOUT characteristics of current minor 100 (which can be seen in FIG. 3), however, are not constant. As shown, the mirrored current IMIRROR increases with an increase in the output voltage VOUT, instead of settling at an example reference current IREF of −1 μA.

To combat the increase of the mirrored current IMIRROR with an increase in the output voltage VOUT of current minor 100, current mirror 400 of FIG. 4 can be used. Here, bias transistors Q3 and Q4 (which are also NMOS transistors and which receive reference voltage VREF) are cascoded with transistors Q1 and Q2 of current mirror 100. The bias transistors Q3 and Q4 help maintain the voltage in saturation. As can be seen in FIG. 5, the mirrored current IMIRROR remains generally constant at the example reference current IREF of −1 μA as output voltage increases.

While the circuitry of FIGS. 1 and 4 is well-known and has been used for CMOS and bipolar transistors for many years, there are emerging technologies that have characteristics that may interfere with the desired performance of similar circuits. Turning to FIG. 6, an example of an emerging technology transistor 600 can be seen; namely transistor 600 is a graphene or carbon nanotube (CNT) transistor. An example of the structure and formation of a graphene or CNT transistor can be found in U.S. Pat. No. 7,687,308, which is incorporated herein by reference for all purposes.

Here, FIG. 6 shows a simplified example of a cross sectional view of a graphene or CNT transistor 600. Similar to CMOS transistors, graphene and CNT transistors have a source, drain, and gate. As shown, the transistor 600 is formed over a dielectric layer 604 on a substrate 602. The source and drain electrodes 606 and 608 are opposite one another with the graphene sheet or CNT 610 formed therebetween. The graphene sheet or CNT 610 generally operates as the channel of transistor 600, so a gate dielectric layer 612 is formed between the graphene sheet or CNT 612 and gate electrode 614 (similar to a CMOS transistor).

The behavior of transistor 600, however, is completely different from a CMOS transistor. Transistor 600 operates as an ambipolar transistor, and the I-V characteristics of transistor 600 can be seen in FIG. 7. When comparing FIG. 7 to FIG. 2, it can easily be observed that developing circuitry for ambipolar transistors (i.e., transistor 600) having similar behavior to known circuitry in CMOS (or bipolar) can be challenging. Accordingly, there is a need for a current mirror circuit using ambipolar transistors.

Some conventional circuits are: U.S. Patent Pre-Grant Publ. No. 2008/0290941; Yang et al., “Triple-Mode Single-Transistor Graphene Amplifier and Its Applications,” ACS Nano, Vol. 4, No. 10, Oct. 12, 2010, pp. 5532-5538; and Abdolahzadegan et al., “MVL Current Mode Circuit Design Through Carbon Nanotube Technology,” European J. of Scientific Research, Vol. 42, No. 1, 2010, pp. 152-163.

### SUMMARY

A preferred embodiment of the present invention, accordingly, provides an apparatus. The apparatus comprises a diode-connected ambipolar transistor, wherein a reference current is applied to the diode-connected transistor; a driven ambipolar transistor that is coupled to the gate of the diode-connected transistor at its gate; a first cascoded ambipolar transistor that is coupled to the drain of the driven ambipolar transistor at its source and the gate of the diode-connected transistor at its gate; a second cascoded ambipolar transistor that is coupled to the source of the driven ambipolar transistor at it drain and the gate of the diode-connected transistor at its gate.

In accordance with a preferred embodiment of the present invention, each of diode-connected ambipolar transistor, the driven ambipolar transistor, the first cascoded ambipolar transistor, and the second cascoded ambipolar transistor further comprises a graphene transistor, a carbon nanotube (CNT) transistor, or a tunneling field effect transistor (TFET).

In accordance with a preferred embodiment of the present invention, the diode-connected ambipolar transistor and the driven ambipolar transistor are about the same size.

In accordance with a preferred embodiment of the present invention, the diode-connected ambipolar transistor further comprises a first ambipolar transistor, and wherein the driven ambipolar transistor further comprises a first output transistor, and wherein apparatus further comprises: a second diode-connected ambipolar transistor that is coupled to the source of the first diode-connected ambipolar transistor at its drain; and a second driven ambipolar transistor that is coupled to the gate of the second diode-connected ambipolar transistor at its gate and the source of the second cascoded ambipolar transistor at its drain.

In accordance with a preferred embodiment of the present invention, an apparatus is provided. The apparatus comprises a node; a first ambipolar transistor that is coupled to the node at its source; a second ambipolar transistor that is coupled to the gate and drain of the first ambipolar transistor at its source, wherein a reference current is applied to the second ambipolar transistor at its drain and gate; a third ambipolar transistor that is coupled to the node at its source and the gate of the first ambipolar transistor at its gate; a fourth ambipolar transistor that is coupled to the drain of the third ambipolar transistor at its source and the gate of the second ambipolar transistor at its gate; a fifth ambipolar transistor that is coupled to the drain of the fourth ambipolar transistor at its source and the gate of the second ambipolar transistor at its gate; and a sixth ambipolar transistor that is coupled to the drain of the fifth ambipolar transistor at its source and the gate of the second ambipolar transistor at its gate, wherein a minor current is applied from the drain of the sixth ambipolar transistor.

In accordance with a preferred embodiment of the present invention, each of the first, second, third, fourth, fifth, and sixth ambipolar transistors further comprises a graphene transistor, a CNT transistor, or a TFET.

In accordance with a preferred embodiment of the present invention, the first and third ambipolar transistors are approximately the same size, and wherein the second and fifth ambipolar transistors are approximately the same size.

In accordance with a preferred embodiment of the present invention, the node is coupled to ground.

In accordance with a preferred embodiment of the present invention, the node is coupled to a negative voltage rail.

In accordance with a preferred embodiment of the present invention, the node is coupled to a positive voltage rail.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a diagram of an example of a conventional current mirror;

FIG. 2 is a diagram depicting the drain current versus gate-source voltage characteristics of a conventional NMOS transistor;

FIG. 3 is a diagram depicting the output current versus output voltage for the current minor of FIG. 1;

FIG. 4 is a diagram of an example of a conventional current mirror with bias transistors;

FIG. 5 is a diagram depicting the output current versus output voltage for the current minor of FIG. 4;

FIG. 6 is a diagram depicting an example of a graphene or CNT transistor;

FIG. 7 is a diagram depicting the drain current versus gate-source voltage characteristics of the transistor of FIG. 6;

FIG. 8 is a diagram depicting the output current versus output voltage for the current minor of FIG. 1 using ambipolar transistors;

FIG. 9 is a diagram depicting the output current versus output voltage for the current minor of FIG. 4 using ambipolar transistors;

FIG. 10 is a diagram depicting an example of a current mirror using ambipolar transistors in accordance with a preferred embodiment of the present invention; and

FIG. 11 is a diagram depicting the output current versus output voltage for the current minor of FIG. 10 using ambipolar transistors.

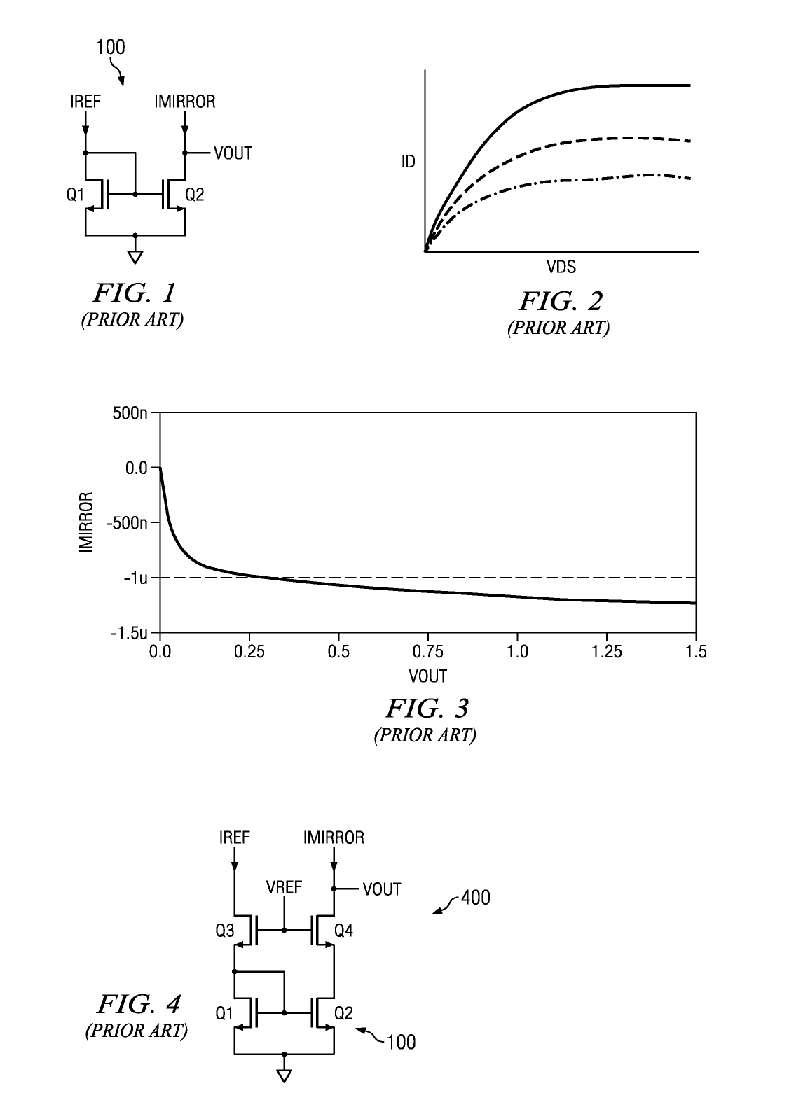

### DETAILED DESCRIPTION

Refer now to the drawings wherein depicted elements are, for the sake of clarity, not necessarily shown to scale and wherein like or similar elements are designated by the same reference numeral through the several views.

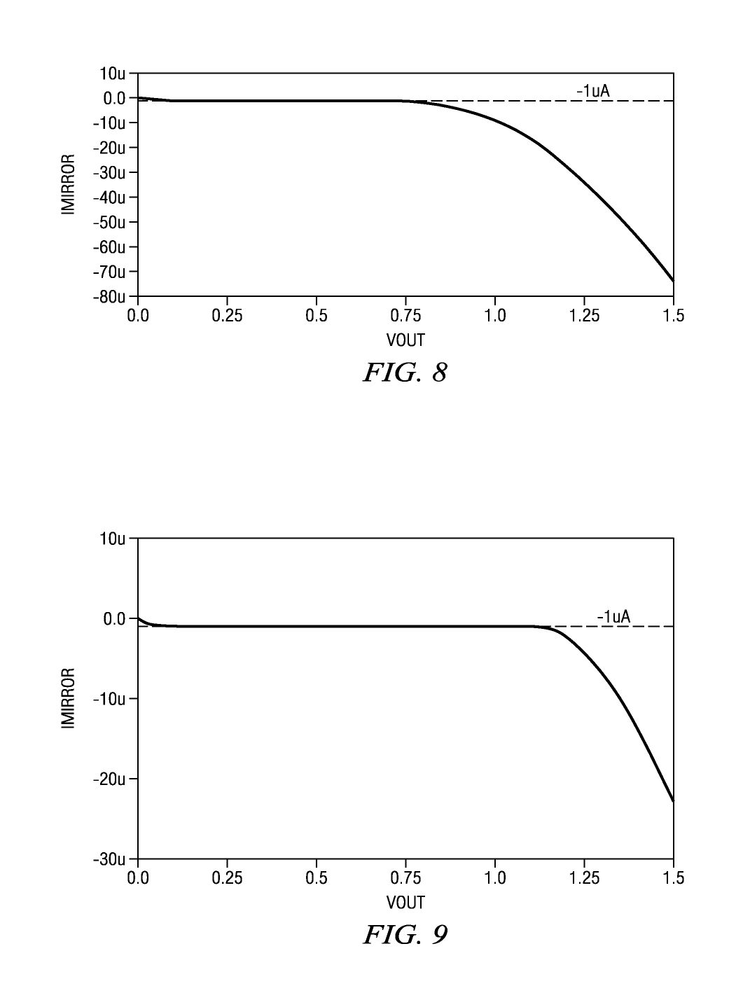

When designing a current minor for use with ambipolar transistors (i.e., graphene transistors, CNT transistors, or tunneling field effect transistors (TFETs)), one may simply attempt to replace transistors Q1 and Q2 of current minor 100 or transistors Q1 through Q4 of current mirror 400 with ambipolar transistors; however, such a circuit will not function as desired. In FIGS. 8 and 9, diagrams of the output current or mirrored current IMIRROR versus output voltage VOUT for current mirrors 100 and 400, respectively, employing ambipolar transistors are shown. Because of the unusual I-V (drain current versus gate-source voltage) characteristics of ambipolar transistors, the mirrored current IMIRROR becomes excessive as the output voltage increases (becoming more than ten times the example reference current IREF of −1 μA at 1.5V, as shown in the examples of FIGS. 8 and 9).

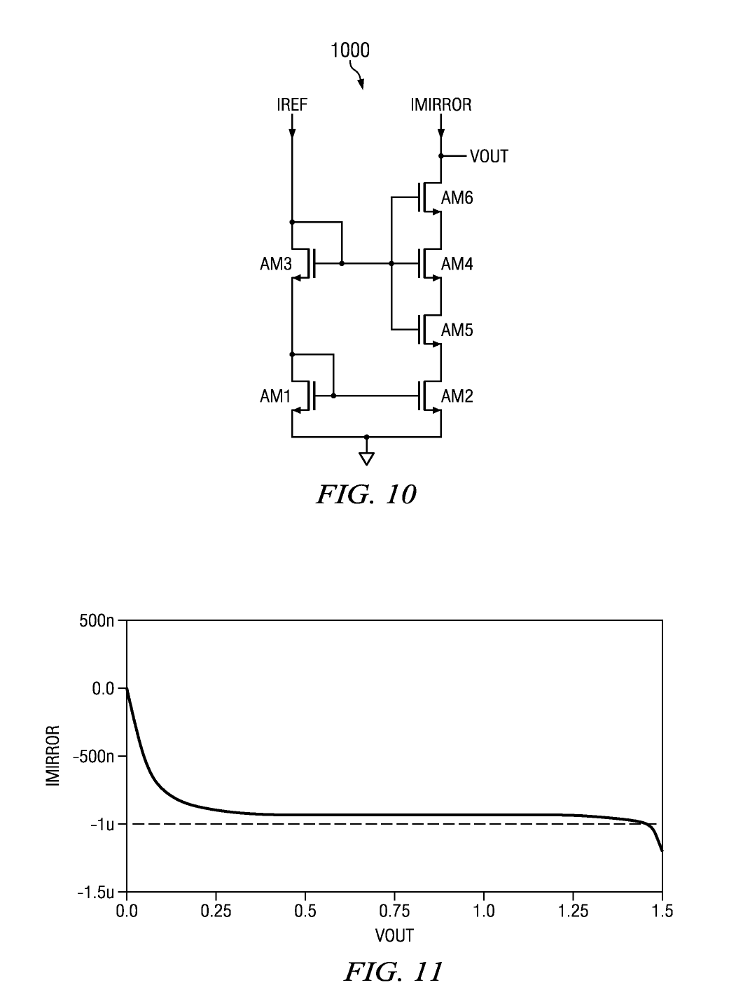

Turning now to FIG. 10, an example of a current mirror 1000 (which uses ambipolar transistors) in accordance with a preferred embodiment of the present invention can be seen. As shown, current minor 1000 generally comprises ambipolar transistors AM1 through AM6 (which can, for example, each be graphene transistors, CNT transistors, or TFETs), which operate as a cascoded current mirror. Namely, transistors AM3/AM4 and AM1/AM2 are generally separate current mirrors coupled together, and each transistor (AM3/AM4 and AM1/AM2) of each current mirror can be matched with one another (i.e., have the same size or aspect ratio). In operation, a reference current IREF can be applied to the drains and gates of diode-connected ambipolar transistors AM3 and AM1 so as to be mirrored by driven transistors AM2 and AM4. To avoid the undesirable increase in the mirrored current IMIRROR with output voltage VOUT, transistors AM5 and AM6 are stacked or cascoded with transistor AM4. The gates of transistors AM5 and AM6 are also generally coupled to the gate of transistor AM3. By including transistors AM5 and AM6, at least one of the transistors AM4 through AM6 remain in a “normal” operating range (i.e., portion of its I-V curve that allows the mirrored current IMIRROR to be generally equal to the reference current IREF) over a wide range of output voltages VOUT because the transistors AM4 through AM6 are cascoded. Additionally, the sources of transistors AM1 and AM2 are coupled together at a common node, which can be coupled to ground, a positive voltage rail, or a negative voltage rail.

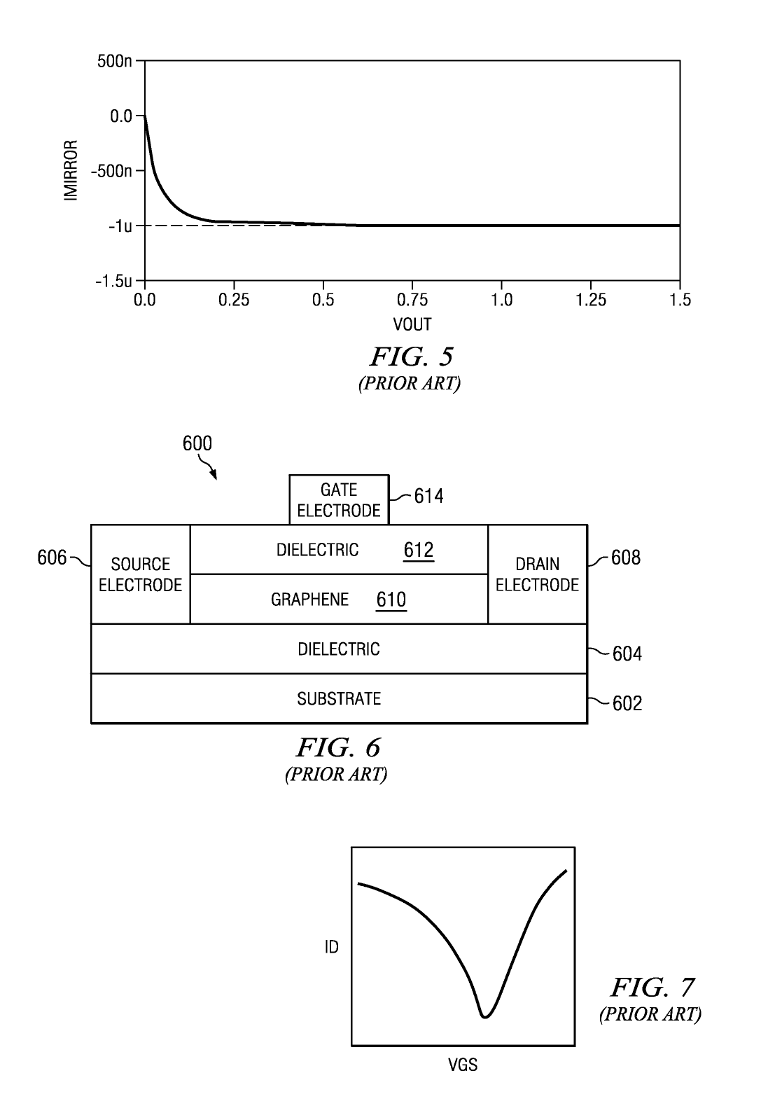

In FIG. 11, the diagram depicting the mirrored current IMIRROR versus output voltage VOUT for current minor 1000 can be seen. As shown, the mirrored current IMIRROR remains generally constant (i.e., close to an example reference current IREF of −1 μA) over a wide range of output voltages VOUT, similar to FIGS. 3 and 5.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a diode-connected ambipolar transistor, wherein a reference current is applied to the diode-connected transistor;
a driven ambipolar transistor that is coupled to the gate of the diode-connected transistor at its gate;
a first cascoded ambipolar transistor that is coupled to the drain of the driven ambipolar transistor at its source and the gate of the diode-connected transistor at its gate; and
a second cascoded ambipolar transistor that is coupled to the source of the driven ambipolar transistor at it drain and the gate of the diode-connected transistor at its gate.

2. The apparatus of claim 1, wherein each of diode-connected ambipolar transistor, the driven ambipolar transistor, the first cascoded ambipolar transistor, and the second cascoded ambipolar transistor further comprises a graphene transistor, a carbon nanotube (CNT) transistor, or a tunneling field effect transistor (TFET).

3. The apparatus of claim 2, wherein the diode-connected ambipolar transistor and the driven ambipolar transistor are about the same size.

4. The apparatus of claim 3, wherein the diode-connected ambipolar transistor further comprises a first ambipolar transistor, and wherein the driven ambipolar transistor further comprises a first output transistor, and wherein apparatus further comprises:
a second diode-connected ambipolar transistor that is coupled to the source of the first diode-connected ambipolar transistor at its drain; and
a second driven ambipolar transistor that is coupled to the gate of the second diode-connected ambipolar transistor at its gate and the source of the second cascoded ambipolar transistor at its drain.

5. An apparatus comprising:
a node;
a first ambipolar transistor that is coupled to the node at its source;
a second ambipolar transistor that is coupled to the gate and drain of the first ambipolar transistor at its source, wherein a reference current is applied to the second ambipolar transistor at its drain and gate;
a third ambipolar transistor that is coupled to the node at its source and the gate of the first ambipolar transistor at its gate;
a fourth ambipolar transistor that is coupled to the drain of the third ambipolar transistor at its source and the gate of the second ambipolar transistor at its gate;
a fifth ambipolar transistor that is coupled to the drain of the fourth ambipolar transistor at its source and the gate of the second ambipolar transistor at its gate; and
a sixth ambipolar transistor that is coupled to the drain of the fifth ambipolar transistor at its source and the gate of the second ambipolar transistor at its gate, wherein a minor current is applied from the drain of the sixth ambipolar transistor.

6. The apparatus of claim 5, wherein each of the first, second, third, fourth, fifth, and sixth ambipolar transistors further comprises a graphene transistor, a CNT transistor, or a TFET.

7. The apparatus of claim 6, wherein the first and third ambipolar transistors are approximately the same size, and wherein the second and fifth ambipolar transistors are approximately the same size.

8. The apparatus of claim 7, wherein the node is coupled to ground.

9. The apparatus of claim 7, wherein the node is coupled to a negative voltage rail.

10. The apparatus of claim 7, wherein the node is coupled to a positive voltage rail.
